(19) United States
(12) Patent Application Publication
(10) Pub. No.: US 2008/0121955 A1
(43) Pub. Date: May 29, 2008

(54) Silicon-based ferroelectric memory material and memory

(75) Inventors: Jia-Min Shieh, HsinChu (TW); An-Thung Cho, Hsinchu (TW); Yi-Fan Lai, HsinChu (TW); Bau-Tong Dai, HsinChu (TW)

Correspondence Address: BIRCH STEWART KOLASCH & BIRCH, PO BOX 747, FALLS CHURCH, VA, 22040-0747, US

(73) Assignee: National Applied Research Laboratories

(21) Appl. No.: 11/604,746

(22) Filed: Nov. 28, 2006

(51) Int. Cl. H01L 27/115

(52) U.S. Cl. 257/295; 257/E27.104

(57) ABSTRACT

There is provided a silicon-based ferroelectric memory material, which includes a mesoporous silica with the nanopores thereon, and high-density arrays of nanocrystalline silicon or germanium quantum dots formed on the inner wall of the nanopores of the mesoporous silica. The silicon-based ferroelectric memory material is substantially composed of silicon and oxygen element, and the process for fabricating such a material is simple and can be done at the low temperature (<400° C.) so that the process for fabricating the silicon-based ferroelectric memory material is compatible with the semiconductor process, and is effective to prevent from cross pollution encountered in the prior art. The ferroelectric memory including the silicon-based ferroelectric memory material has the same advantages, such as high speed and long-life, as those of the conventional ferroelectric memory.

### BACKGROUND OF THE INVENTION

1. Field of the Invention

The present invention relates generally to a ferroelectric memory material and a non-volatile memory, and in particular to a silicon-based ferroelectric memory material and a memory formed therewith.

2. The Prior Arts

With development of the information industry and provision of more applications of the information media, various kinds of memory have increasingly become important. Among them, the electronic memory is undoubtedly the most important one. The electronic memories may be functionally categorized into two types. One is random access memory (RAM), which possesses an access time down to below 100 ns. However, the RAM does not provide a permanent memory function. The other one is non-volatile read only memory (ROM), such as flash memory, which has a permanent memory function, but has an access time greater than 1 ms.

Floating-gate memory can be the most commonly used non-volatile memory and has been utilized in a variety of electronic products. However, as the semiconductor process is developed down to below 70 nanometer, the scalability of the floating-gate memory has met a challenge. It is because that the floating-gate memory can not has superior charging capability and high memory performance any more in case that the dimension of the floating-gate memory is manufactured down to the nano-level.

To solve the above-mentioned problems, a nano quantum dot memory device has been suggested, in which the nano quantum dots existing in a thin film, instead of the poly-silicon floating gate, is used as the floating gate for charge storage. Although many quantum dot memories are made from silicon-based materials and are compatible with the semiconductor processes, the processes of nano quantum dot memory devices are not easy to be controlled, which limits their developments. Furthermore, since the quantum dot memory device is operated in a similar manner with the conventional floating-gate memory, i.e. operated by moving charges, it has the disadvantages of relatively large power consumption, long access time and reduced lifetime.

For solving this problem, a novel ferroelectric memory has been set forth. Since the ferroelectric memory is not involved with any charge motion and collision during the access process, it has a relatively fast access time (approximately 10⁻⁹ sec), a prolonged retention time and a relatively low power consumption, compared with that of the conventional floating-gate memory. Further, the ferroelectric memory can have theoretically limitless operation cycles. In spite of the above-mentioned advantages, the ferroelectric memory has encountered with the process compatibility problem for a long time. The ferroelectric memory can not be compatible with the semiconductor process since the conventional ferroelectric memory includes a thin film of a non-silicon based lead zirconate titanate (PZT) ferroelectric memory material. Such a ferroelectric memory material can bring about a cross pollution during semiconductor process, and also it has poor thermal stability, and is dependent on the substrate. In addition, the ferroelectric memory also suffers the problem of limitation on device miniature.

In this regard, how to make the fabrication of the ferroelectric memory to be compatible with the semiconductor process and to be avoided cross pollution has become an important issue in the current fabrication process of the ferroelectric memory.

### SUMMARY OF THE INVENTION

Accordingly, it is an objective of the present invention to provide a silicon-based ferroelectric memory material and a memory formed therewith. The silicon-based ferroelectric memory material is compatible with the semiconductor process, and is effective to prevent from cross pollution encountered in the prior art.

To achieve the objective of the present invention, there is provided a silicon-based ferroelectric memory material comprising a mesoporous silica (MS) with a plurality of nanopores thereon, and the arrays of nanocrystalline (nc) silicon (or germanium) quantum dots attached to the inner walls of the nanopores of the mesoporous silica by the surface bonds contributing to ferroelectricity.

In the present invention, because the microstructure of silicon-based ferroelectric memory material with nanopores having nc silicon (or germanium) quantum dots formed thereon is composed of silicon and oxygen and also the silicon-based ferroelectric memory is fabricated at a temperature of below 400° C., the process for fabricating memory from the silicon-based ferroelectric memory material is compatible with the semiconductor process, and meanwhile can avoid the cross pollution. In addition, the silicon-based ferroelectric memory is very easy to be formed on a glass substrate and even a plastic substrate

In another aspect, the present invention provides a silicon-based ferroelectric memory which comprises a ferroelectric memory layer fabricated from the silicon-based ferroelectric memory material as mentioned above.

The present invention provides a silicon-based memory comprises a memory layer fabricated by treating the silicon-based ferroelectric material having nc silicon (or germanium) quantum dots formed thereon at a temperature of above 1000° C. After annealing at 1000° C., the ferrelectric characteristic disappears because the surface states or the surface bonds contributing to ferroelectricity are lost or broken; and the nano quantum dots in the nanopores of the memory material are effectively separated from one another due to the break of the surface bonds. Then, the characteristics of the charge storage type memory material will exhibit.

Other objectives, advantages and efficacies may be understood with reference to the description and drawings below.

### BRIEF DESCRIPTION OF THE DRAWINGS

The accompanying drawings, which are included to provide a further understanding of the invention and are incorporated in and constitute a part of this application, illustrate embodiments of the invention and together with the description serve to explain the principle of the invention. In the drawings:

FIG. 1 is a schematic diagram for illustrating the formation of silicon nanocrystal (nc-Si) or germanium nanocrystal (nc-Ge) quantum dots in the nanopores of the mesoporous silica using the plasma assisted atomic layer deposition (PAALD) method according to the present invention;

FIGS. 2A and 2B are a perspective and detailed view of the inside of the nanopores of the mesoporous silica in a metal-oxide-semiconductor (MOS) structure and a cross sectional view of the MOS structure with a ferroelectric memory layer formed of the mesoporous silica according to the present invention, respectively;

FIG. 3 is a transmission electron microscopy (TEM) image of a cross section of the mesoporous silica with nanopores having nc-Si therein, in which an enlarged view of the TEM image is provided at the upper left portion.

FIG. 4 is a Secondary Ion Mass Spectroscopy (SIMS) profile with respect to nc germanium content in the nanopores of the mesoporous silica after growth of the germanium quantum dots according to the present invention;

FIG. 5 is a photoluminescence (PL) spectrum diagram of the mesoporous silica with nanopores having nc-Si therein according to the present invention, in which curve (a) is obtained in a case prior to annealing process, and curve (b) is obtained in a case after the annealing process;

FIG. 6 is an X-ray photoemission spectroscopy (XPS) diagram of the mesoporous silica with nanopores having nc-Ge therein according to the present invention, in which data samples □ are obtained in the case before the annealing and samples are obtained in the case after the annealing;

FIG. 7 is a dipole moment-electric field (P-E) diagram of the MOS structure of the non-volatile memory device, which includes the ferroelectric memory layer according to the present invention;

FIG. 8 is a spontaneous dipole moment diagram of the ferroelectric memory layer of the silicon-based ferroelectric memory under different temperatures according to the present invention; and

FIG. 9 is a voltage-capacitance diagram of the ferroelectric memory layer of the MOS structure of the non-volatile memory device according to the present invention, in which curve (a) is obtained before the annealing process and curve (b) is obtained after the annealing process.

### DETAILED DESCRIPTION OF THE PREFERRED EMBODIMENT

The present invention will be described in detail taken with the preferred embodiments with reference to the annexed drawings.

The present invention discloses a silicon-based ferroelectric memory material comprising a mesoporous silica (abbreviated herein as MS) with a plurality of nanopores thereon; and high density nanocrystalline silicon (abbreviated herein as nc-Si), or germanium (abbreviated herein as nc-Ge) quantum dot arrays located on the inner wall of the nanopores of the mesoporous silica.

A conventional mesoporous silica has a porosity of up to 75%, and therefore its surface area is very large (about 1000 m²/g), and the nanopore size of mesoporous silica is adjustable (2 to 10 nm). The adjustable nanopore sizes mean that the nanopore sizes are varied with the preparation conditions. In the present invention, the silicon-based ferroelectric memory material is prepared by forming the three-dimensional high density arrays of nc-Si (or nc-Ge) quantum dots on the inner wall of the nanopores of the mesoporous silica by the conventional technology.

The size of nc-Si and nc-Ge in the quantum dot arrays is not limited, but is preferably 2 to 5 nm for accommodation within each of the nanopores on the MS. The density of the quantum dots in the high density arrays of nc-Si (or nc-Ge) quantum dots is not limited, but is preferably 1×10¹⁷ to 1×10¹⁹ cm³ and more preferably 5×10¹⁷ to 5×10¹⁸ cm³ for enabling the silicon-based ferroelectric memory material used in the present invention to have a better ferroelectric memory characteristic.

Any suitable conventional fabrication method can be utilized for forming the nc-Si (or nc-Ge) quantum dot arrays in the nanopores of the MS, for example, ion implantation, oxidation/precipitation, chemical vapor deposition (CVD), high density inductively coupled plasma (ICP), plasma enhanced CVD (PECVD), and plasma assisted atomic layer deposition (PAALD), but not limited thereto. Among them, the PAALD method is most preferred. This is because that PAALD can not only provide a significantly greater density of the nc-Si (or nc-Ge) quantum dots but also successfully overcome the problems of prolonged process time, over-temperature, and interface degradation.

Take the PAALD method as an example. The silicon-based ferroelectric memory material is prepared by using mesoporous silica as a nanotemplate and repeatedly performing the steps of the exposure of the nucleating sites for forming the quantum dots, and the formation of quantum dot crystals at a low temperature (less than 400° C.) utilizing the hydrogen (H₂) plasma along with the silane (SiH₄) plasma in order to form the high density uniformly spaced three-dimensional array of nc-Si (or nc-Ge) quantum dots having well controlled surface-states and quantum confinement (QC) on the inner walls of the nanopores of the nanotemplate.

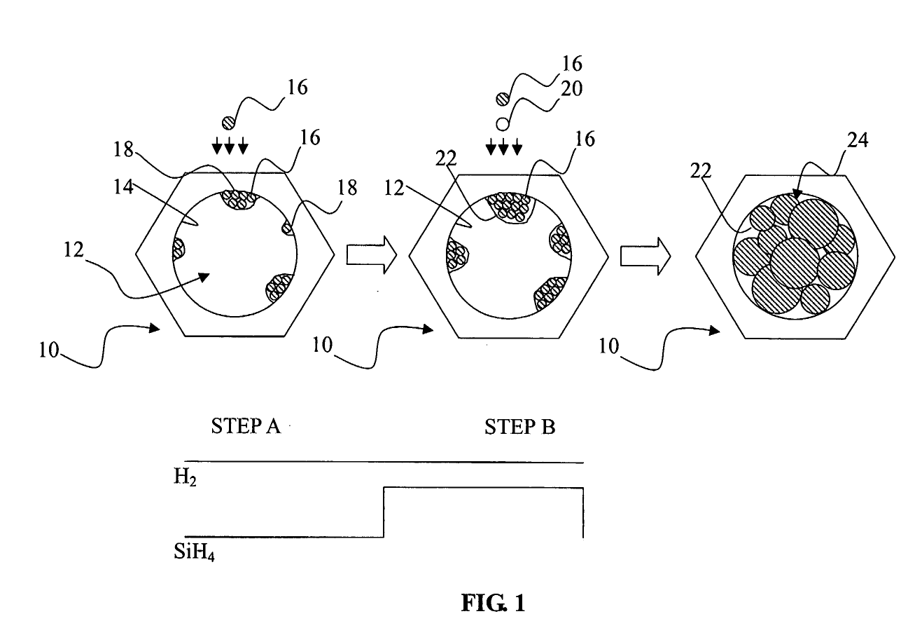

Referring to FIG. 1, a schematic diagram for illustrating the formation of the nc-Si (or nc-Ge) quantum dot arrays in the nanopores of the mesoporous silica by the PAALD process according to the present invention is shown therein. In a single cycle, the PAALD process includes to steps, i.e. step A and step B. In step A, the nucleating sites for forming the quantum dots are exposed. In step B, the quantum dots are formed on the exposed nucleating sites. Specifically, in step A, a hydrogen (H₂) plasma 16 is applied into the nanopores 12 of the mesoporous silica 10 to break a portion of molecules on the surfaces of the inner walls 14 of the nanopores 12 of the MS. At this time, the pore channels for diffusing the reactive molecules are formed and the nucleating sites (nucleation points) 18 for forming the quantum dots are exposed. In step B, SiH₄ 20 and H₂ plasma 16 are applied to the nanopores 12 of the mesoporous silica 10 by the PAALD method so as to enable the quantum dots 22 to be formed at the nucleating sites 18. That is, the nano quantum dots 22 are deposited on the inner walls 14 of the nanopores 12. Then, the process cycle of steps A and B is repeated so that the exposure of the nucleating sites 18 and the formation of the quantum dots 22 are repeatedly conducted. As such, the uniformly spaced three-dimensional nc-Si (or nc-Ge) quantum dot arrays 24 are finally formed in the nanopores 12 of the mesoporous silica 10.

In the formation of the nanoclusters of the quantum dots in the nanopores of the mesoporous silica by PAALD, several reactions are involved. First, SiHₙ (or GeHₙ) generated by the plasmas diffuses in the form of nanoclusters to the nanopores of the mesoporous silica and then absorbed and buried therein. At this time, a plenty of Si—OH groups on the inner walls of the nanopores of the mesoporous silica are activated through a hydrogen-elimination reaction (HER) [Si—OH+SiHₙ(GeHₙ)→Si—O—SiHₘ(GeHₘ)+H₂] to serve as anchoring sites for SiHₙ (or GeHₙ). Subsequently, Si—O—SiHₘ(GeHₘ) is converted into Siₙ(Geₙ) nanoclusters in the nanopores of the mesoporous silica by a further hydrogen-elimination reaction [Si—O—SiHₘ(GeHₘ)→Si—O—Siₙ(Geₙ)+H₂], and thus the quantum dots are formed.

Because the deionized particles with high kinetic energy are used in the process cycles of the exposure of the nucleating sites and the formation of the quantum dots, the process can be conducted at low temperature (lower than 400° C.) at high speed (less than two minutes) for large area preparation, and can be compatible with the very large scale integration (VLSI) process.

The process for forming the mesoporous silica with nanopores having nc silicon (or germanium) quantum dots formed thereon can be conducted according to the conventional fabrication process. For example, a precursor solution for forming the mesoporous silica is firstly spinned and coated on a P-type silicon substrate. The precursor solution can be prepared by adding an alcohol solution containing triblock copolymers (such as Pluronic P-123, abbreviated as P123) to the acid-catalyzed silica sol-gel. The acid-catalyzed silica sol-gel is prepared by, for example, refluxing a mixture of tetraethyl orthosilicate (TEOS), water, HCl, and alcohol for 60 to 120 minutes under a temperature of 60 to 80° C., wherein the molar ratio of TEOS, water, HCl, and alcohol in mixture is 1:0.008-0.3:3.5-5.0:0.003-0.03:40, respectively. In addition, the precursor solution is preferably aged at the room temperature for 3 to 6 hours previously and then spinned and coated on the silicon substrate at a speed of 3,000 rpm. Finally, the coated silicon substrate is dried for 4 to 6 hours at 40 to 60° C. and then baked at 100 to 120° C. for 3 hours. As such, the preparation of the mesoporous silica with nanopores is accomplished.

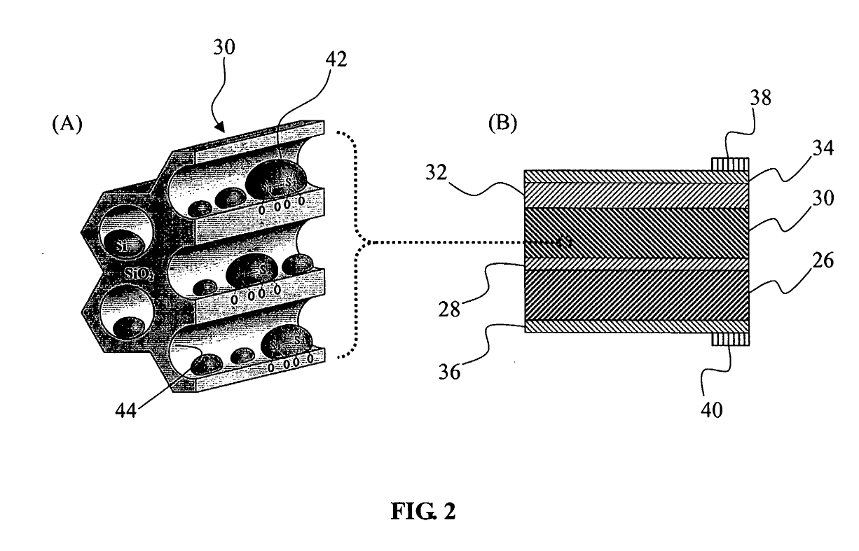

Referring to FIG. 2B, a cross sectional view of a metal-oxide-silicon (MOS) structure in a non-volatile memory, comprising a ferroelectric memory layer made from the silicon-based ferroelectric memory material according to the present invention is depicted therein. The MOS structure includes a P-type silicon substrate 26, a first buffer layer 28 formed on the P-type silicon substrate 26, a mesoporous silica 30 formed on the first buffer layer 28, a second buffer layer 32 formed on the mesoporous silica 30, an upper electrode 34 formed on the second buffer layer 32 and a lower electrode 36 formed below the P-type silicon-substrate 26. The electrical connection pads 38, 40 may be disposed on the upper and lower electrodes 34 and 36, respective. Referring to FIG. 2A, it is a perspective and detailed diagram of the mesoporous silica 30 with nanopores. From this figure, it may be seen that the nc-Si quantum dots 42 are formed from bottom to top on the inner walls 44 of the nanopores of the mesoporous silica 30.

In the above, the first and second buffer layers may be formed from such as silicon dioxide and the upper and lower electrodes may be formed from such as aluminum.

The nano-quantum dot arrays of the silicon-based ferroelectric memory material in accordance with the present invention has an excellent illumination efficiency (>1%) at blue wavelengths, meaning that it has a huge number of excitons (electron-hole pairs) or dipole centers. Therefore, the silicon-based ferroelectric memory material is very suitable to be used as a memory material.

The silicon-based ferroelectric memory material exhibits excellent storing characteristic due to the polarizations induced by dipoles or dipole centers generated by the surface-states at the nc-Si/SiO₂ interface.

The silicon-based ferroelectric memory material in accordance with the present invention has an excellent thermal stability since it has a very high Curie temperature, but it was surprisingly found that when the silicon-based ferroelectric memory material of the present invention was subjected to a thermal. treatment of up to 1,000° C., its surface-states contributing to ferroelectricity were lost, or its surface bonds contributing to ferroelectricity were broken, and in this case, the memory will come back to the traditional charge storage mode.

### EXAMPLE 1

### Preparation of the MOS Structure Including Ferroelectric Memory Layer Formed From the Silicon-Based Ferroelectric Memory Material

At first, a 5 nm thickness silicon dioxide buffer layer is deposited onto a P-type silicon substrate. Then, an 85 nm thickness mesoporous silica is spinned and coated onto the buffer layer.

The mesoporous silica is formed by the following process. At first, the precursor solution is prepared by adding an alcohol solution containing triblock copolymers (such as Pluronic P-123, abbreviated as P123) to the acid-catalyzed silica sol-gel. The acid-catalyzed silica sol-gel is prepared by, for example, refluxing a mixture of tetraethyl orthosilicate (TEOS), water, HCl, and alcohol for 60 to 120 minutes under a temperature of 60 to 80° C., wherein the molar ratio of TEOS, water, HCl, and alcohol in mixture is 1:0.008-0.3:3.5-5.0:0.003-0.03:40, respectively. Furthermore, the precursor solution is aged at the room temperature for 3 to 6 hours and then spinned and coated on the silicon substrate at a speed of 3,000 rpm in a period of 30 seconds. Finally, the coated silicon substrate is dried for 4 to 6 hours at 40 to 60° C. and then baked at 100 to 120° C. for 3 hours. As such, the mesoporous silica serving as a nano-template for growing nc-Si (or nc-Ge) is obtained. In essence, the mesoporous silica are prepared by the mechanism of liquid-crystallization, and the nanostructures of the mesoporous silica are formed by molecular self-assembly process during liquid-crystallization.

Next, the PAALD technology (silicon hydride (1 sccm) and hydrogen (200 sccm)/hydrogen (200 sccm) are impulsed in each duty cycle at a ratio of 1 sec/3 sec) is used to form nc-Si on the inner walls of the pore channels of the mesoporous silica. Thus, high density nc-Si quantum dot arrays are formed in the aforementioned pore channels of the mesoporous silica shown in FIG. 2A.

Finally, a 10 nm thickness silicon dioxide are deposited on the mesoporous silica, and then aluminum is used to form an upper and lower electrodes, completing the formation of the MOS structure, shown in FIG. 2B.

Since all the processes in Example 1 are sequentially undertaken in high vacuum environment, the quality and characteristic of nc-Si/SiO₂ interface can be well-controlled.

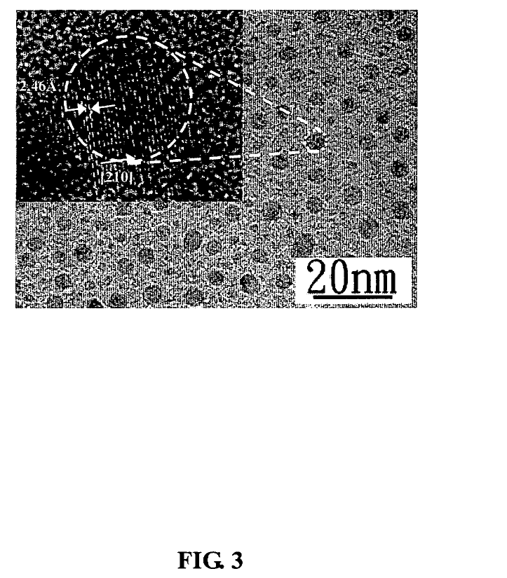

The cross section of the mesoporous silica layer of thus formed MOS structure is analyzed by using the transmission electron microscopy (TEM). The image obtained is shown in FIG. 3.

Referring to FIG. 3, the TEM image of the cross section of the mesoporous silica layer with nanopores having nc silicon quantum dots formed thereon is shown. The enlarged image at the upper left portion of FIG. 3 shows obvious lattice fringes—this indicates that the nc-Si quantum dots have a good crystallization quality and each of the quantum dots has a dimension of 2 to 5 nm, and the density of the quantum dots is up to 2.5×10¹⁸ cm³.

### EXAMPLE 2

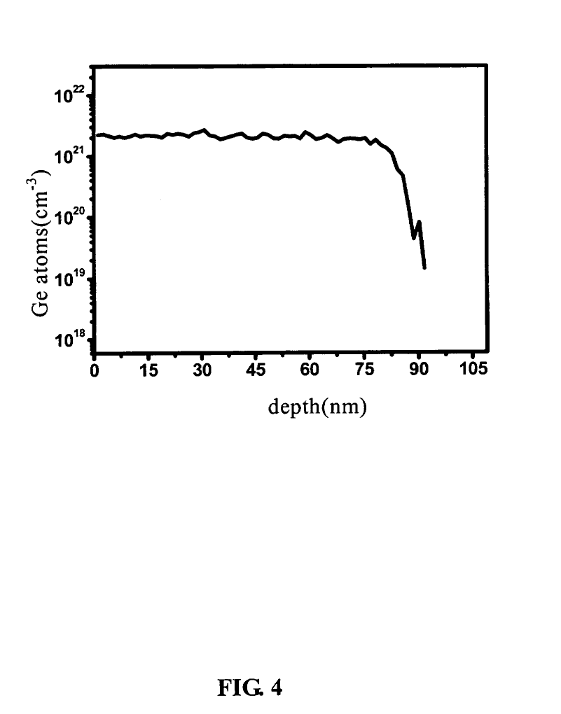

The MOS structure is fabricated in the same manner as that of Example 1, except that nc-Ge is used in replace of nc-Si as the quantum dots formed on the inner walls of the pore channels of the mesoporous silica. The elemental depth profiling measurement of the mesoporous silica layer of the MOS structure fabricated in Example 2 is made by using the secondary ion mass spectroscopy (SIMS), and the SIMS depth profiling obtained is shown in FIG. 4. According to the SMIS depth profiling and the TEM image, it can be known that the nc-Ge quantum dots are formed with a size of 2 to 5 nm and their density is up to 2×10¹⁸ cm³. Thus, it can be confirmed that nc-Si and nc-Ge in the mesoporous silica have the similar growth mechanism.

### The Spectra of the Mesoporous Silica Layer Having nc Silicon or nc Germanium Quantum Dots Formed Thereon

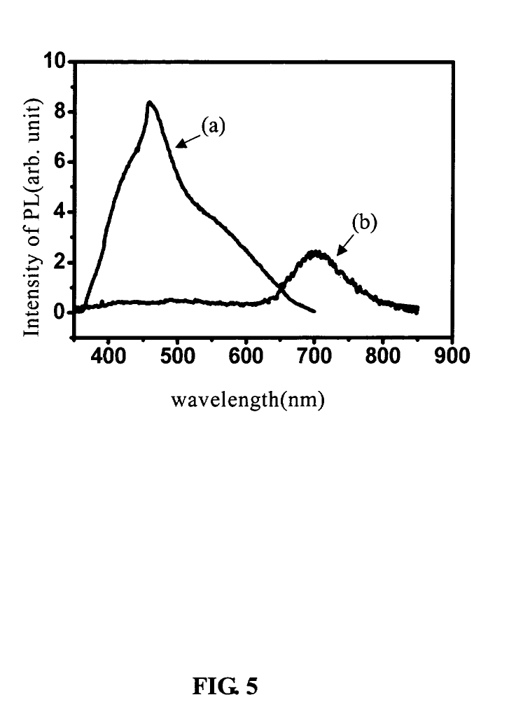

The mesoporous silica layer of the MOS structure of Example 1 is measured for its photoluminescence (PL) intensity by using an excitation He—Cd laser (325 nm) at 30 mW at the room temperature, and the photoluminescence spectrum thereof is shown in FIG. 5.

FIG. 5 is the photoluminescence spectrum of the mesoporous silica layer with nanopores having nc silicon quantum dots formed thereon. In FIG. 5, it can be seen that a high-intensity blue light (wavelength (λ)=460 nm, dominated by the surface-states) is excited in the mesoporous silica, where the blue photoluminescence is related to the neutral oxygen vacancy (NOV) defects [≡Si—Si≡] in the mesoporous silica, and the nc-Si plays a role on blue light sensitizing by generating more photoexcited carriers. These photoexcited carriers are trapped at the surface oxygen defects and recombined to emit high-intensity blue light. Therefore, the mesoporous silica has an excellent Si/SiO₂ interface, i.e. a large number of surface state levels.

Then, the mesoporous silica is further subjected to the thermal process at a temperature of 1000° C. At this time, the blue photoluminescence disappears and a new red light wavelengths (at about 700 nm, dominated by the quantum dots) curve (b) appears. This is because that the above defects are effectively removed owing to the thermal process and the separated Si nanocrystals are formed. The 700 nm red light is generated by the band-to-band recombination of the separated nanocrystals and thus the quantum-confined size-effect is presented.

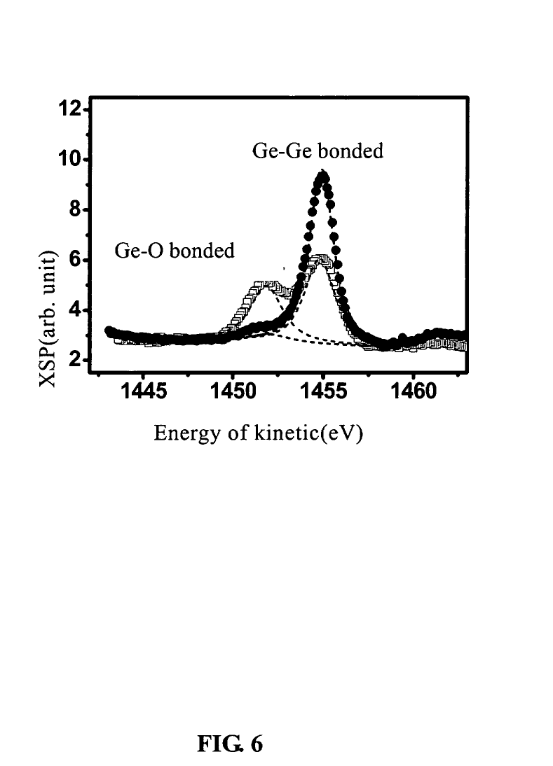

Thereafter, the bond-structure change in the mesoporous silica after the thermal process is further studied by using X-ray photoemission spectroscopy (XPS). The signals of the nanocrystals are separated from those of the mesoporous silica. The nc-Ge is used in replace of the nc-Si in the mesoporous silica. The XPS result is shown in FIG. 6.

FIG. 6 is an X-ray photoemission spectrum of the mesoporous silica with nanopores having nc germanium quantum dots formed thereon. Referring to FIG. 6, it can be seen that the peak area ratio of Ge—O bond to Ge—Ge bond is up to 0.8:1 for the mesoporous silica containing the nc-Ge quantum dots. It is demonstrated that the mesoporous silica has a very good nc-Ge/SiO₂ surface (i.e. the mesoporous silica are more likely to have the dipole centers and the surface states). After the thermal treatment, the Ge—O peak disappears while the Ge—Ge peak becomes stronger, indicating the fact that the Ge—O bonds on the nc-Ge/SiO₂ interface are broken, i.e. the interface structure formed by the Ge—O and Si—O bonds are changed by the thermal and annealing process so that the buried nanocrystals are transformed into the separated quantum dots.

### The Polarization Analysis of the Mesoporous Silica Layer Having nc Silicon or nc Germanium Quantum Dots Formed Thereon

Here, the electrical characteristics of the nc-Si buried in the mesoporous silica layer of the MOS structure fabricated in Example 1 are analyzed.

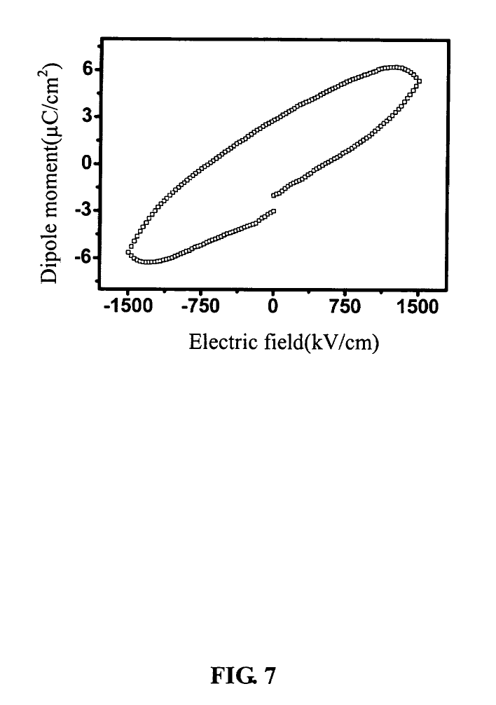

The existence of the electrical polarization in the mesoporous silica with the nc-Si quantum dots buried therein are confirmed by using the polarization-electric field (P-E) analysis technology, and the results are shown in FIG. 7.

Referring to FIG. 7, it can be known that there are a large number of dipole centers in the mesoporous silica having nc-Si or nc-Ge thereon, and thus the mesoporous silica having nc-Si or nc-Ge thereon is a silicon-based ferroelectric material. After a thermal process (at 1000° C.), the ferrelectric characteristic disappears because the surface states are lost.

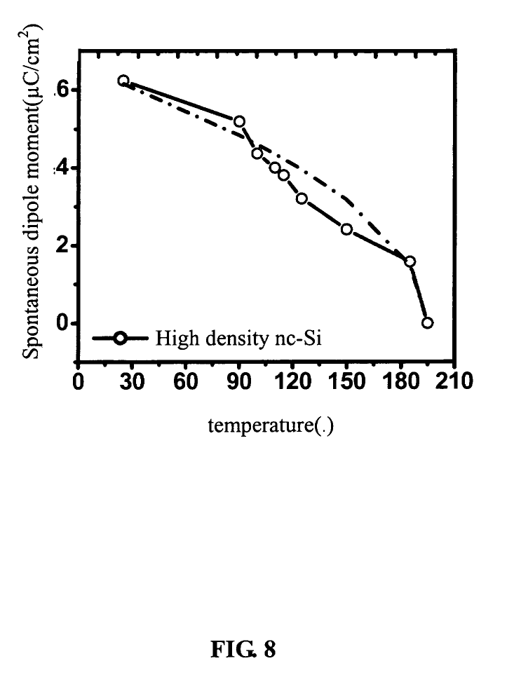

This fact supports that the permanent dipole moments of the mesoporous silica layer having nc-Si or nc-Ge thereon of the present invention are related to the oxygen defects on the nc-Si/SiO₂ interface. The interface bonding structure is considerably stable and the thus formed ferroelectricity (spontaneous polarization Ps) can be maintained at a temperature up to 195° C. (refer to FIG. 8).

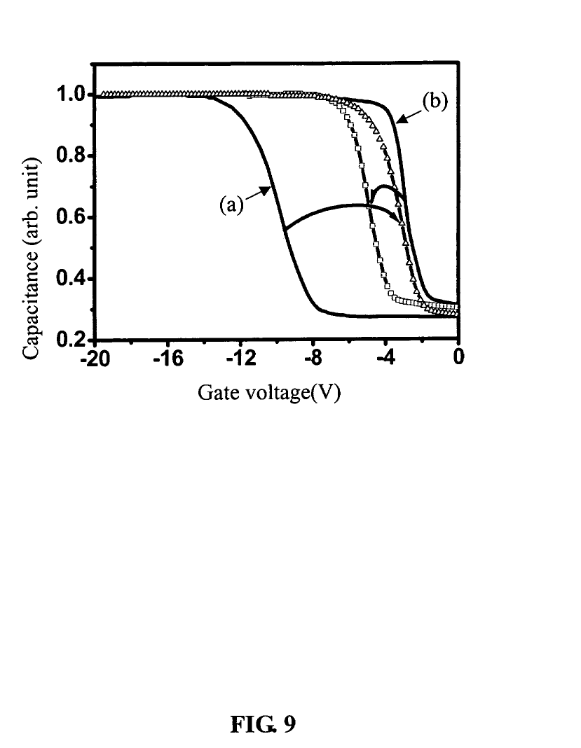

According to the known theory, the region for the surface potential is changed from depletion to inversion when the electrical polarization exceeds 0.1 μC/cm2. In the prior art, the ferroelectricity-induced C—V memory window ΔV is determined according to the equation ΔV=2E_{c}×d, wherein d is a thickness of a ferrelectric layer and Ec is a coercive field. Referring to FIG. 9, a voltage-capacitance (C—V) analysis graph of the MOS structure including the ferroelectric memory layer of the non-volatile memory device according to the present invention is shown therein. From curve (a) in this figure, it can be seen that there is a C—V shift of 50% between 5 V and −17 V operating voltage, meaning that the ferroelectric memory formed with the ferroelectric memory layer of the present invention has an excellent ferroelectric memory characteristic. However, as to the mesoporous silica having nc-Si or nc-Ge thereon with relatively strong coercive field, it is found that the C—V memory window does not monotonically increase with the density of the nc-Si quantum dots (or the coercive field Ec) increases, meaning the charging effect occurring on the sample containing high-density quantum dots of nc-Si can not be ignored.

In addition, the mesoporous silica having nc-Si or nc-Ge thereon is further put into a thermal process at a high temperature. From the curve (b) in this figure, it can be seen that a charge storage mode is presented on the MOS structure after the high-temperature thermal process is conducted. This result confirmed that the composite material nc-Si (or nc-Ge) quantum dots/silica can become a ferrelectric memory or a charge storage type memory by the process control.

Although the present invention has been described with reference to the preferred embodiment thereof, it is apparent to those skilled in the art that a variety of modifications and changes may be made without departing from the scope of the present invention which is intended to be defined by the appended claims.

What is claimed is:

1. A silicon-based ferroelectric memory material, comprising:
a mesoporous silica with a plurality of nanopores thereon; and
a plurality of quantum dot arrays composed of a plurality of nanocrystals, which are attached to a plurality of inner walls of the nanopores by a plurality of surface bonds contributing to ferroelectricity,
wherein the nanocrystals are silicon nanocrystals or germanium nanocrystals.

2. The material as claimed in claim 1, wherein the high-density quantum dot arrays have a density of 1×10¹⁷ to 1×10¹⁹ dots/cm³.

3. The material as claimed in claim 1, wherein the nanocrystals have a diameter of 2 to 5 nm.

4. The material as claimed in claim 1, wherein the high-density quantum dot arrays are formed by stacking the nanocrystals in three dimensions.

5. The material as claimed in claim 1, wherein each of the nanopores has a diameter of 2 to 10 nm.

6. The material as claimed in claim 1, wherein the quantum dot arrays are formed on the inner walls of the nanopores of the mesoporous silica by a method selected from the group consisting of ion implantation, oxidation/precipitation, chemical vapor deposition, inductively coupled plasma, plasma enhanced chemical vapor deposition, and plasma assisted atomic layer deposition.

7. The material as claimed in claim 1, wherein the quantum dot arrays are formed on the inner walls of the nanopores of the mesoporous silica by the plasma assisted atomic layer deposition.

8. A silicon-based memory material formed by treating the silicon-based ferroelectric memory material as claimed in claim 1 at a temperature of more than 1000° C. to break the surface bonds contributing to ferroelectricity.

9. A ferroelectric memory, comprising:
a silicon substrate;
a first buffer formed on the silicon substrate;
a ferroelectric memory layer formed on the first buffer layer; and
a second buffer layer formed on the ferroelectric memory layer,
wherein the ferroelectric memory layer is made of a silicon-based ferroelectric memory material as claimed in claim 1.

10. A silicon-based memory, comprising:
a silicon substrate;
a first buffer formed on the silicon substrate;
a memory layer formed on the first buffer layer; and
a second buffer layer formed on the memory layer,
wherein the memory layer is made of the silicon-based memory material as claimed in claim 8.
